(19) United States
(12) Patent Application Publication
(10) Pub. No.: US 2014/0318612 A1
(43) Pub. Date: Oct. 30, 2014

(54) MANUFACTURING METHOD OF SILICON SOLAR CELL AND SILICON SOLAR CELL

(71) Applicant: Terasolar Energy Materials Corp. Ltd., MiaoLi County (TW)

(72) Inventors: Yi-Chin Chou, Miaoli County (TW); Chia-Yun Liu, Kaohsiung City (TW); Cheng-Liang Cheng, Hsinchu City (TW); Pin-Sheng Wang, Hsinchu County (TW); Bang-Hao Wu, Hsinchu County (TW)

(73) Assignee: Terasolar Energy Materials Corp. Ltd., MiaoLi County (TW)

(21) Appl. No.: 14/073,878

(22) Filed: Nov. 7, 2013

(30) Foreign Application Priority Data
Apr. 30, 2013 (TW) 102115465

(51) Int. Cl. H01L 31/0236; H01L 31/0224; H01L 31/18

(52) U.S. Cl. CPC H01L 31/02366; H01L 31/1804; H01L 31/022425
USPC 136/256; 438/71

(57) ABSTRACT

A manufacturing method of a silicon solar cell and the silicon solar cell thereof are provided. A silicon substrate formed with a doped layer on a light receiving surface thereof is provided. First and second dielectric layers are respectively formed on the light receiving surface and the rear surface of the silicon substrate. A patterned second dielectric layer with an opening and a groove in the silicon substrate are formed by partially removing the second dielectric layer and the silicon substrate. First and second electrode compositions are respectively formed on the light receiving surface and the rear surface, and the second electrode composition is filled into the groove. After performing a high temperature process to co-firing the silicon substrate and the first and second electrode compositions, a first electrode and a second electrode are respectively formed on the light receiving surface and the rear surface.

### CROSS-REFERENCE TO RELATED APPLICATION

This application claims the priority benefit of Taiwan application serial no. 102115465, filed on Apr. 30, 2013. The entirety of the above-mentioned patent application is hereby incorporated by reference herein and made a part of this specification.

### BACKGROUND

1. Field of the Present Disclosure

The present invention relates to an optoelectronic device and the manufacturing method thereof. More particularly, the present invention relates to a manufacturing method of a silicon solar cell and a silicon solar cell.

2. Description of Related Art

As solar energy is a kind of unlimited and non-polluting energy, it has been highly expected as the substitute solution of current petrol energy which has long suffered from pollution and shortage problems. Solar cells can directly convert solar energy to electrical energy and has drawn more and more attentions these years.

The solar cell is a photovoltaic device. The typical structure of a solar cell can be divided into four parts: a silicon substrate, a P—N diode, an anti-reflection layer and a plurality of metal electrodes. The general principle of the solar cell is to convert solar energy into electron-hole pairs whose driving force is provided through the P—N diode, and then output electrical energy by the conduction of positive and negative electrodes.

Passivated emitter and rear contact (PERC) type solar cells with high efficiency have been proposed, of which the dielectric layer is mainly formed on the backside of the substrate, and a part of the back electrode form a eutectic layer with the silicon substrate via the opening of the dielectric layer, and the performance of the solar cell using this structure can be improved.

Specifically, the conventional PERC solar cell is usually fabricated by forming the dielectric layer on the back surface, removing a part of the dielectric layer to form an opening without damaging the surface of the silicon substrate, followed by forming the back electrode on the dielectric layer and forming a eutectic layer within the opening of the dielectric layer. However, if the parameters for removing the dielectric layer, e.g., depth, etc., are not properly controlled during the process of forming the opening in the dielectric layer, the eutectic layer formed in the opening will be unstable and even voids will be produced, thereby affecting the overall efficiency and yield of the solar cell.

### SUMMARY

The present invention provides a manufacturing method for a silicon solar cell, which offers larger process windows for manufacturing silicon solar cells with high conversion efficiency.

The present invention provides a manufacturing method of a silicon solar cell comprising the following steps. A silicon substrate formed with a doped layer on the light receiving surface of the silicon substrate is provided. Later, a first dielectric layer is formed on the light receiving surface and a second dielectric layer is formed on the rear surface of the silicon substrate opposite to the light receiving surface. By locally removing the second dielectric layer and removing a portion of the underlying silicon substrate with a laser, a patterned second dielectric layer and at least one groove are formed. The patterned second dielectric layer exposes the at least one groove. A first electrode composition is formed on the light receiving surface and a second electrode composition is formed on the rear surface. The second electrode composition is filled into the at least one groove. After performing a high temperature process to co-firing the silicon substrate and the first electrode composition as well as the second electrode composition, a first electrode is formed on the light receiving surface and a second electrode is formed on the rear surface.

The present invention provides a manufacturing method of a silicon solar cell comprising the following steps. A silicon substrate formed with a doped layer on the light receiving surface of the silicon substrate is provided. Later, a first dielectric layer is formed on the light receiving surface and a second dielectric layer is formed on the rear surface of the silicon substrate opposite to the light receiving surface. By locally removing the second dielectric layer and removing a portion of the underlying silicon substrate with a laser, a patterned second dielectric layer and at least one groove are formed. The patterned second dielectric layer exposes the at least one groove. A first electrode composition is formed on the light receiving surface and a second and a third electrode compositions are formed on the rear surface. The second electrode composition is filled into the at least one groove. After performing a high temperature process to co-firing the silicon substrate and the first, second and third electrode compositions, a first electrode is formed on the light receiving surface and a second and a third electrode are formed on the rear surface.

As embodied and broadly described herein, the step of forming the doped layer further comprises forming a high-concentration doped region and a low-concentration doped region in different regions of the doped layer on the light receiving surface. Specifically, the high-concentration doped region is formed on a region of the light receiving surface corresponding to the first electrode and the sheet resistance of the high-concentration doped region is equal to or less than 70 ohm/square. The low-concentration doped region is located on a region of the light receiving surface outside the region corresponding to the first electrode, and the sheet resistance of the low-concentration doped region is greater than 70 ohms/square. In one embodiment, the high-concentration doped region and the low-concentration doped region are included on regions of the light receiving surface outside the region corresponding to the first electrode.

As embodied and broadly described herein, the width of the at least one groove is greater than 5 microns and the depth of the at least one groove is greater than 0.5 microns. In addition, after co-firing of the second electrode composition and the silicon substrate, the bottom contour of the at least one groove has an approximately symmetrical or substantially symmetrical shape along the thickness direction of the silicon substrate.

As embodied and broadly described herein, the step of forming a first electrode composition on the light receiving surface comprises screen printing a silver paste on the light receiving surface. The step of forming a second electrode composition on the rear surface comprises screen printing an aluminum paste on the rear surface. Additionally, the manufacturing method may further comprise screen printing a silver paste on the rear surface to form a third electrode composition on the rear surface. In this case, the aluminum paste is screen printed into at least a portion of the at least one groove.

As embodied and broadly described herein, the patterned second dielectric layer on the silicon substrate has at least one opening, and the pattern of the at least one opening of the second dielectric layer includes a line, a dot, a dashed line, a circular line, a polygon, an irregular shape or combinations thereof. Also, a cross-sectional shape of the at least one groove along the thickness direction of the silicon substrate includes a square, a triangle, a circle, an oval, an arc, a multi-arc-shape, a polygon, an irregular shape or combinations thereof.

Also, the present invention provides a silicon solar cell fabricated by the manufacturing methods mentioned above.

The present invention also provides a silicon solar cell, comprising a silicon substrate, a first dielectric layer, a patterned second dielectric layer, a first electrode and a second electrode. The silicon substrate is formed with a doped layer on the light receiving surface and a recess on the rear surface opposite to the light receiving surface. The recess along the thickness direction of the silicon substrate has an approximately symmetrical or substantially symmetrical contour. The first dielectric layer is disposed on the light receiving surface of the silicon substrate. The patterned second dielectric layer is located on the rear surface of the silicon substrate opposite to the light receiving surface, and the patterned second dielectric layer exposes the recess. The first electrode is located on the light receiving surface. The second electrode is located on the rear surface. The structure of the eutectic product formed from co-firing between the second electrode and the silicon substrate, has a shape whose central depth is smaller than its marginal depth.

As embodied and broadly described herein, the doped layer further comprises at least a high-concentration doped region and a low-concentration doped region in different regions of the doped layer on the light receiving surface.

By using the manufacturing method of silicon solar cell(s) provided in the present invention, the reaction area between the back electrode and the silicon substrate is increased, and the eutectic structure without voids is generated due to sufficient reaction between the back electrode and the silicon substrate. Also, the local back surface field of the silicon solar cell has a larger thickness, thus improving the efficiency of silicon solar cells. Furthermore, the edge(s) of the generated local back surface field of the silicon solar cell is relatively uniform, which further enhances the efficiency of the silicon solar cell. Further, since the laser is used in the present invention to locally remove the second dielectric layer and a portion of the underlying silicon substrate so as to form the groove, the groove formation is less likely to be affected by the surface morphology of the silicon substrate and the thickness of the dielectric layer. Hence, the manufacturing method of the silicon solar cell in the present invention has a larger process window, and high performance silicon solar cells may be produced at lower costs.

In order to make the aforementioned and other objects, features and advantages of the present invention comprehensible, embodiments accompanied with figures are described in detail below. It is to be understood that both of the foregoing general description and the following detailed description are exemplary, and are intended to provide further explanation of this disclosure as claimed.

### BRIEF DESCRIPTION OF THE DRAWINGS

The accompanying drawings are included to provide a further understanding of this disclosure, and are incorporated in and constitute a part of this specification. The drawings illustrate embodiments of this disclosure and, together with the description, serve to explain the principles of this disclosure.

FIGS. 1A and 1B illustrate schematic cross-sectional views of a silicon solar cell structure at different positions according to one embodiment of the present invention.

FIG. 2 is a flowchart of a manufacturing method for a silicon solar cell according to one embodiment of the present invention.

FIGS. 3A to 3C are partially enlarged views of the local back surface field of the silicon solar cell in FIG. 1 during the manufacturing step of FIG. 2.

FIGS. 4A to 4C are scanning electron microscope images of FIGS. 3A to 3C according to one embodiment of the present invention.

FIGS. 5A to 5C display Comparative Examples of silicon solar cell of the present invention.

FIGS. 6A to 6C are scanning electron microscope images of FIGS. 5A to 5C according to one embodiment of the present invention.

### DESCRIPTION OF EMBODIMENTS

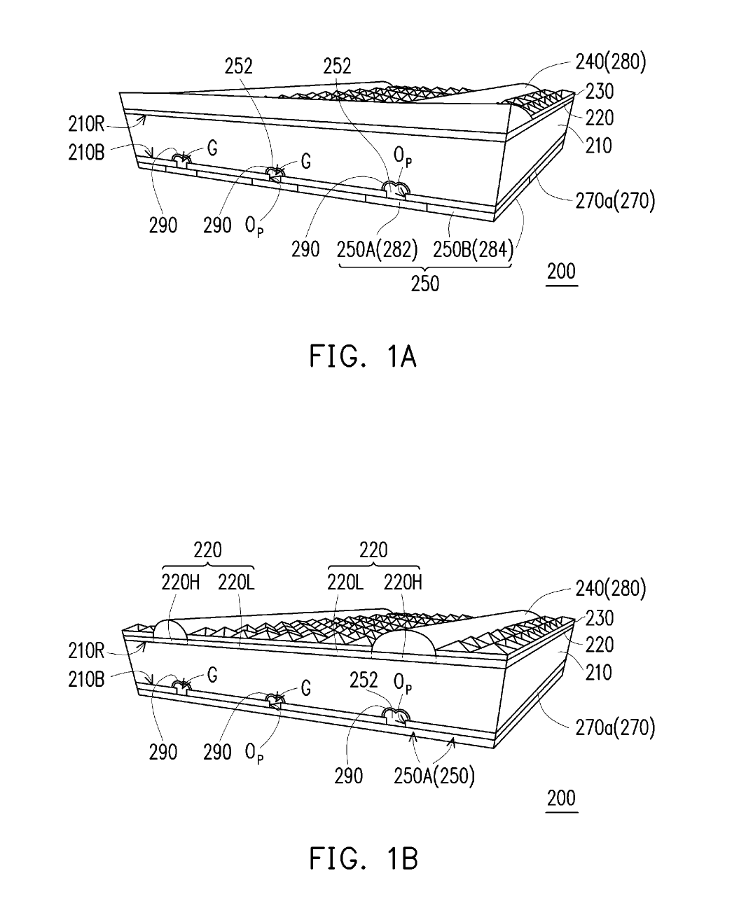

FIGS. 1A and 1B illustrate schematic cross-sectional views of a silicon solar cell structure at different positions according to one embodiment of the present invention. FIG. 1A is a schematic cross-sectional view along the bus bar of the front electrode, and FIG. 1B is a schematic cross-sectional view along regions outside of the bus bar. Refer to FIG. 1A, the solar cell in the present embodiment is of the passivated emitter and rear contact (PERC) structure, including mainly the solar cell substrate (e.g., a silicon substrate 210), the doped layer 220 located on the light receiving surface 210R, the first dielectric layer 230, and the first electrode 240, the second dielectric layer 270 located on the rear surface 210B, the second electrode (aluminum electrode) 250A and the third electrode (silver electrode) 250B. FIG. 1B only shows the second electrode (aluminum electrode) 250A.

Specifically, as shown in FIG. 1A and FIG. 1B, in the structure of the silicon solar cell 200 of the present embodiment, for example, the light receiving surface 210R of p-type silicon wafer is a roughened surface or exhibits pyramid-shaped structures (pyramid texture) thereon, so that the reflection of sunlight or light hit on the solar cell is reduced and the utilization of sunlight is enhanced. A doped layer 220 is located on the light receiving surface 210R. A first dielectric layer 230 is located between the first electrode 240 (i.e. front side electrode) and the silicon substrate 210, and the material of the first dielectric layer 230 may be, for example, silicon nitride (SiNx), silicon oxide (SiO₂) or a combination thereof.

On the other hand, on the rear surface 210B of the silicon solar cell 200 of the present embodiment, a back electrode 250 constituted by the second electrode 250A (aluminum electrode) and the third electrode 250B (silver electrode) and a patterned second dielectric layer 270 between the silicon substrate 210 and the back electrode 250 are included. As shown in FIGS. 1A and 1B, the patterned second dielectric layer 270 has an opening Op, a portion of the second electrode 250A forms a eutectic layer 252 with the silicon substrate 210 within the opening Op of the second dielectric layer 270 so as to be connected with the silicon substrate 210. A local back surface field 290 is formed between the eutectic layer 252 and the silicon substrate 210.

Particularly, the silicon solar cell 200 of the present embodiment may be produced by the manufacturing method of the silicon solar cell in the present invention, the extent and area of reaction between the second electrode 250A and the silicon substrate 210 can be enlarged for better formation of the eutectic layer 252, thereby increasing the efficiency of the silicon solar cell 200. In addition, the local back surface field 290 of the silicon solar cell 200 is thereby formed with greater thickness and better uniformity, and the special contour is thus formed as shown in FIGS. 1A and 1B. Further, due to the sufficient reaction, the eutectic layer 252 is formed with a uniform, void-free structure. The following paragraphs describe the manufacturing method for a silicon solar cell of the present invention.

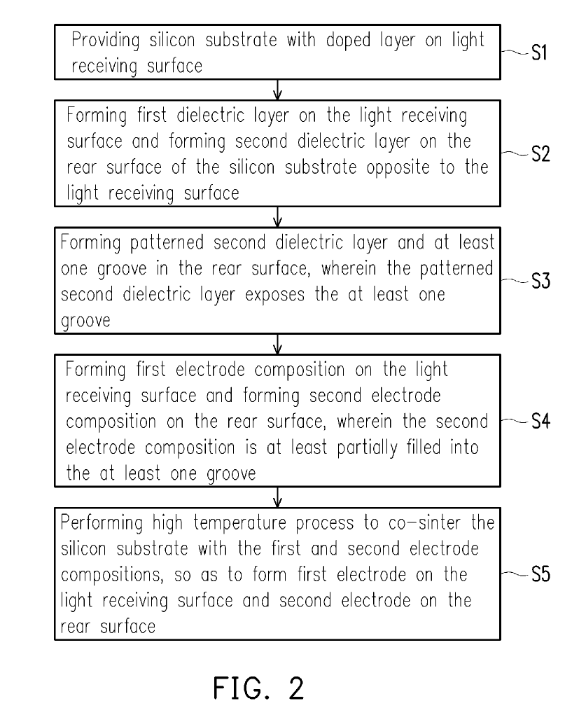

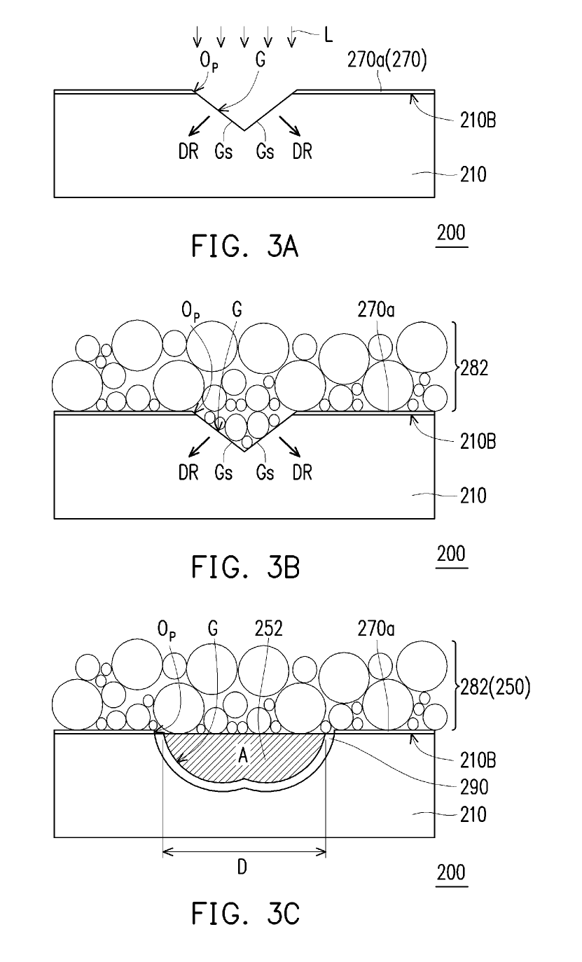

FIG. 2 is a flowchart of a manufacturing method for a silicon solar cell according to one embodiment of the present invention. FIGS. 3A to 3C are partially enlarged views of the local back surface field located in the groove of the silicon solar cell in FIG. 1 during the manufacturing step of FIG. 2.

Referring to step S1 in FIG. 2 and FIG. 1, the silicon substrate 210 having the doped layer 220 formed on the light receiving surface 210R is provided. The silicon substrate 210 is, for example, a p-type silicon wafer, and the p-type silicon wafer can be a silicon wafer doped with boron or gallium, and the silicon wafer may be a single crystalline silicon wafer or polycrystalline silicon wafer. In addition, the doped layer 220 may be formed by doping the P-type silicon wafer with the Group V element (e.g., phosphorus (P) or arsenic (As)).

It is noted that, in one embodiment, the doping concentration of the doped layer 220 formed on the light receiving surface 210R of the silicon substrate 210 may be the same. In another embodiment, the high-concentration doped region 220H and low-concentration doped region 220L can be formed on different regions of the light receiving surface 210R of the silicon substrate 210.

Specifically, as shown in FIG. 1B, for example, the region of the doped layer 220 corresponding to the first electrode 240 is doped with high concentration to form the high-concentration doped region 220H in the doped layer 220, so that the surface resistivity of the high-concentration doped region 220H of the doped layer 220 is, for example, equal to or less than 70 ohm/square. On the other hand, other regions of the doped layer 220 outside the region corresponding to the first electrode 240 is doped with low concentration to form the low-concentration doped region 220L, so that the surface resistivity of the low-concentration doped region 220L of the doped layer 220 is, for example, larger than 70 ohm/square. Of course, it is also possible to dope regions of the doped layer 220 outside the region corresponding to the first electrode 240 to form the aforementioned low-concentration doped region 220L and high-concentration doped region 220H at the same time. The scope of the present invention is not limited to the embodiments herein.

By forming the low-concentration doped region 220L and high-concentration doped region 220H in different regions of the doped layer 220 on the light receiving surface 210R, the conversion efficiency of the silicon solar cell 200 can be further improved. Specifically, considering the conversion efficiency of the silicon solar cell 200 having the doped layer 220 of the same doping concentration being set to 1, the conversion efficiency of the silicon solar cell 200 having the doped layer 220 with different doping concentrations, after normalization, is further increased by approximately 3%.

Next, referring to Step S2 in FIG. 2 and FIGS. 1A and 1B, a first dielectric layer 230 is formed on the light receiving surface 210R, and the second dielectric layer 270 is formed on the rear surface 210B of the silicon substrate 210 opposite to the light receiving surface 210R. Specifically, the first dielectric layer 230 may be a single layer or a multilayer structure of SiO₂, SiₓN_{y}, SiₓN_{y}H_{z}, SiₓO_{y}N_{z}, SiC, or a combination thereof, and the second dielectric layer 270 can be a single layer or a multilayer structure of AlₓO_{y}, SiO₂, SiₓN_{y}, Si_{X}N_{y}H_{Z}, Si_{X}O_{y}N_{Z}, or a combination thereof.

Referring to Step S3 of FIG. 2, FIGS. 1A, 1B and 3A, at least portions of the second dielectric layer 270 on the rear surface 210B and the silicon substrate 210 are removed to form a patterned second dielectric layer 270a and to form at least one groove G at the same time on the rear surface 210B of the silicon substrate 210. The patterned second dielectric layer 270a exposes the groove G, and the width of the groove G is greater than 5 microns and the depth of the groove G is greater than 0.5 microns, for example. The process of removing the second dielectric layer 270 and the silicon substrate 210 may be, for example, laser process, etching paste process or photolithography process. The present invention is not limited thereto.

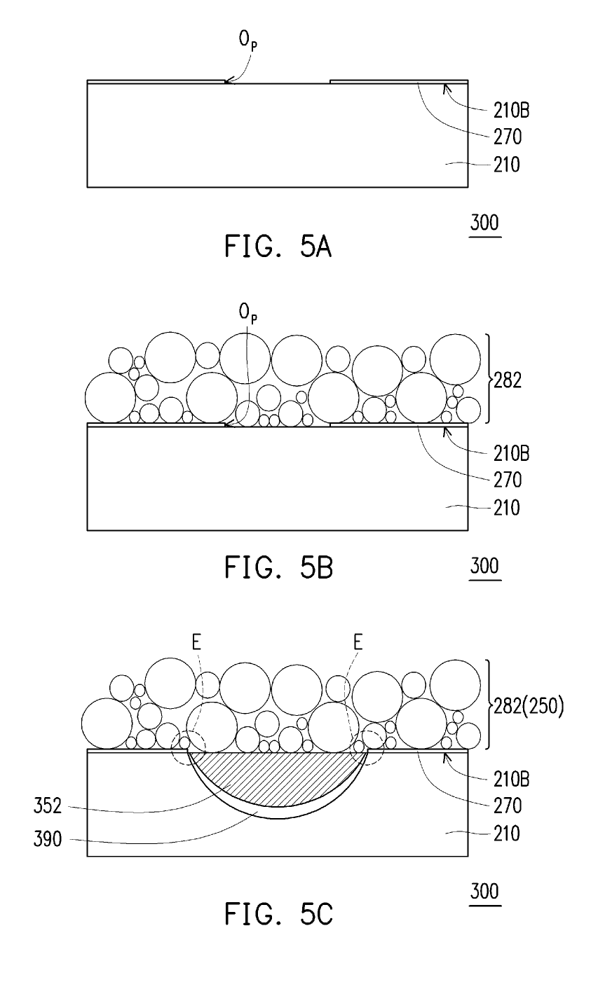

In particular, in the present embodiment, a laser L is used to locally remove the second dielectric layer 270 on the rear surface 210B and the underlying silicon substrate 210. The laser L, for example, possesses pulse width in the order of nanoseconds. In details, for the manufacturing method of the silicon solar cell 200 in the present invention, the energy of the laser L is employed to impact the second dielectric layer 270 and the underlying silicon substrate 210, which destructs the surface morphology of the silicon substrate 210 and forms the structure of the groove G in the thickness direction of the silicon substrate 210. In other words, the process window of the laser L is not limited by the surface morphology of the silicon substrate 210 or the thickness of the second dielectric layer 270. The laser L is different from those general lasers that merely remove the second dielectric layer 270 without damaging the surface of the silicon substrate (see Comparative Examples of FIGS. 5A-5C).

The groove G as shown in FIG. 3A is formed by the manufacturing method of the present invention. As shown, the groove G in the silicon solar cell has two bottom surfaces Gs. In other words, the groove G in this embodiment has a triangle cross-sectional profile along the thickness direction of the silicon substrate. Owing to the profile of such groove G, the second electrode composition 282 filled in the groove G in the follow-up process may react (such as co-firing) with the silicon substrate 210 in a plurality of reaction directions DR. On the other hand, since the vicinity of the groove G of the silicon substrate 210 becomes slightly loose due to the bombardment of the laser L, such structural changes can make the second electrode composition 282 filled in the groove G co-firing more easily and fully with the silicon substrate 210 in the subsequent process. Accordingly, by doing so, the silicon solar cell 200 has better conversion efficiency.

Of course, the shape of the grooves G can be controlled by adjusting the process parameters of the laser L, so that the cross-sectional contour of the groove G along the thickness direction of the silicon substrate 210 may be shaped as a square, a triangle, a circle, an oval, an arc, a multi-arc-shape, a polygon, an irregular shape or combinations thereof. The scope of the present invention is not limited thereto. Further, the opening Op of the second dielectric layer 270 formed on the rear surface 210B of the silicon substrate 210 via the laser L may present the pattern shaped as lines, dots, dashed lines, circular lines, polygons, irregular shapes or combinations thereof, adjustable according to the product needs.

Then referring to Step S4 in FIG. 2, FIGS. 1A, 1B and 3B, the first electrode composition 280 and the second electrode composition 282 are respectively formed on the light receiving surface 210R and on the rear surface 210B. In the present embodiment, the third electrode composition 284 is further formed on the rear surface 210B. For example, the silver paste is screen printed on the light receiving surface 210R to form the first electrode 240, the silver paste and the aluminum paste are screen printed on the rear surface 210B to form the third electrode 250B and the second electrode 250A. In addition, the aluminum paste, for example, is screen printed in the region of the groove G.

As shown in FIG. 3B, the second electrode composition 282 (aluminum paste) fills in the groove G of the silicon substrate 210, and in the present embodiment, the average particle diameter of the aluminum particles in the aluminum paste ranges, for example, from 0.5 microns to 10 microns, and the aluminum particles of the aluminum paste can be at least partially filled into the groove G.

Next, referring to Step S5 of FIG. 2, FIGS. 1A, 1B and 3C, a high-temperature process is performed to co-firing the silicon substrate 210 and the first electrode composition 280 as well as the silicon substrate 210 and the second electrode composition 282, so that the first electrode 240 and the second electrode 250A and the third electrode 250B are respectively formed on the light receiving surface 210R and on the rear surface 210B of the silicon substrate 210. The peak (highest) temperature of the high-temperature process, for example, is greater than 600° C., while the eutectic temperature of aluminum-silicon is approximately at 577° C. Hence, the aluminum-silicon eutectic layer (Al—Si eutectic layer) 252 is formed from the silicon material in the groove G and the second electrode composition 282 (for example, the aluminum paste). Because the laser L is used in the present invention to penetrate through the second dielectric layer 270 and remove a part of the silicon substrate 210 for forming the groove G at the same time, during the step of firing, the second electrode composition 282 (e.g., aluminum paste) located in the groove G can diffuse into the silicon substrate 210 through the at least two bottom surfaces Gs of the groove G. As shown in FIG. 3B, the aluminum in the groove G of the silicon substrate 210 can diffuse toward at least two reaction directions DR vertical to the bottom surface(s) of the groove G, so that the reaction area of aluminum and silicon is increased and the specific profile of the eutectic layer 252 is formed as shown in FIG. 3C. For example, the eutectic layer 252 at the center of the groove G has a depth (central depth) smaller than the depth of the eutectic layer 252 at the edges (marginal depth), so that better firing reaction and more uniform local back surface field 290 occur at the edges of the eutectic layer 252. In other words, with the silicon solar electrode as described, the silicon substrate 210 has a more uniform local back surface field 290.

Further, as shown in FIG. 3C, because the groove G of the silicon substrate 210 and the aluminum paste have sufficient reaction areas, the extent of reaction between aluminum and silicon is enhanced for better eutectic formation, without the need of damage removal steps before filling the second electrode composition 282 into the groove. Therefore, the formed eutectic layer 252 can have void-free structure accompanied with uniform local back surface field 290.

In addition, it is noted that the coverage area of the second dielectric layer 270 on the rear surface 210B of the silicon substrate 210 is in positive correlation with the survival rate of the carrier(s). In other words, the larger the coverage area of the second dielectric layer 270 is, the survival rate of the carrier(s) is prolonged because the recombination of the generated carrier may be minimized with the protection of the dielectric layer. On the other hand, the Al—Si eutectic area (typically the area of the opening Op of the second dielectric layer 270) associates with the collection rate of the carrier. In other words, when the opening Op of the second dielectric layer 270 is bigger, the generated carrier can be more effectively collected and drawn, thereby improving the carrier collection rate. According to the conventional art, since the rear surface area of the silicon substrate 210 is fixed, the sum of the coverage area of the second dielectric layer 270 and the opening area of the second dielectric layer 270 is also fixed. In conventional silicon solar cells technology, a tradeoff exists between the survival rate and the carrier collection rate of the carriers and two conditions cannot be satisfied at the same time.

However, for the silicon solar cell of the present invention, the groove G is deliberately formed in the silicon substrate 210 by the laser L. With the premise of not reducing the coverage area of the second dielectric layer 270, the two bottom surfaces Gs of the groove G in contact with the silicon substrate 210 increase the Al—Si reaction area of the eutectic layer 252, thereby enhancing the survival rate and the carrier collection rate of the carrier simultaneously and improving the conversion efficiency of the silicon solar cell.

In the present invention, the second dielectric layer 270 and the groove G are partially removed by the laser L. That is, there is no limitations that the energy of the laser L can not destroy the surface morphology of the silicon substrate 210 and the laser energy of the laser L may be strong enough to penetrate through the second dielectric layer 270 and completely remove the second dielectric layer 270 on the region reserved for groove(s) (to-be-formed groove), so that even the second dielectric layer 270 located on the edge(s) of the to-be-formed groove can also be completely removed without residues (compared with Comparative Example in FIG. 5C). In this way, the local back surface field of the silicon substrate manufactured by the manufacturing method of the present invention is shown in FIG. 3C, and the local back surface field 290 formed in the groove G has a uniform thickness, which further enhances the conversion efficiency of the silicon solar cell 200.

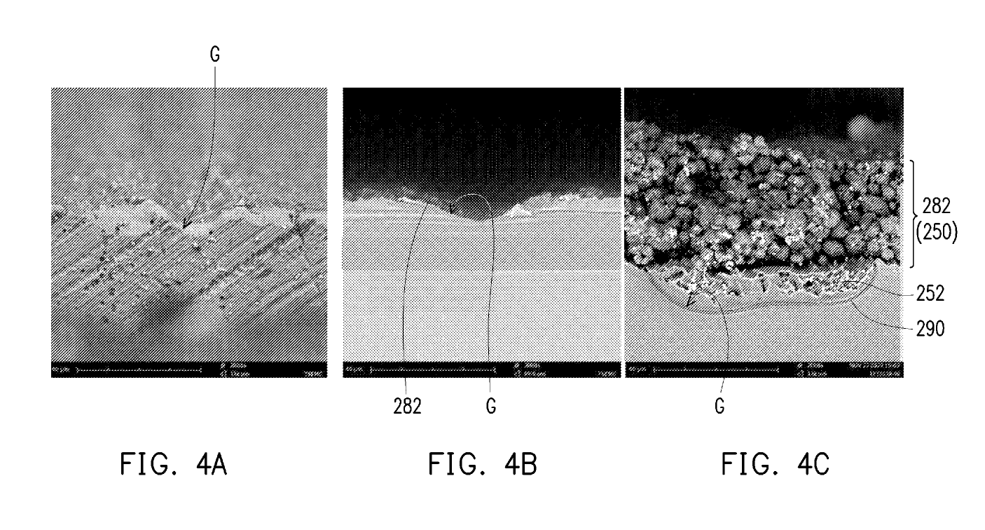

FIGS. 4A to 4C are scanning electron microscope images of FIGS. 3A to 3C according to one embodiment of the present invention. Referring to FIGS. 4A and 3A, a part of the silicon substrate 210 is removed by the laser L to form the groove G. Also seen in FIGS. 4B and 3B, the second electrode composition 282 is formed in the groove G. From FIGS. 4C and 3C, the Al—Si eutectic layer 252 formed in the groove G has a profile of two arcs with an inflection point at the junction of the two arcs, so that the central depth of the Al—Si eutectic layer 252 is smaller than the marginal depth of the Al—Si eutectic layer 252 at the edge of the groove G

### Comparative Example

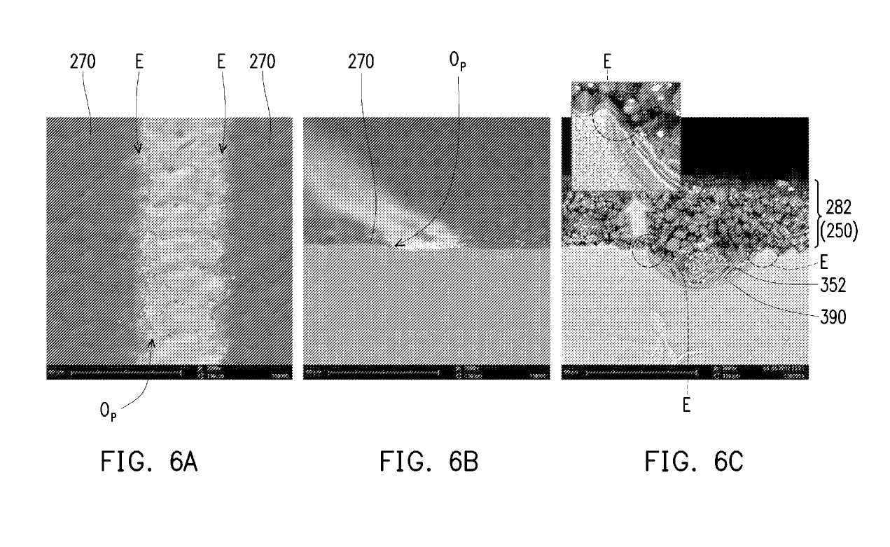

FIGS. 5A to 5C display Comparative Examples of silicon solar cell of the present invention, while FIGS. 6A to 6C are scanning electron microscope images of FIGS. 5A to 5C according to one embodiment of the present invention. Referring to FIGS. 5A and 6A, the second dielectric layer 270 is removed by the laser L without damaging the rear surface 210B of the silicon substrate 210 and the opening Op is formed in the second dielectric layer 270. The laser L is a picosecond laser, and the second dielectric layer 270 located near the edge E of the opening Op is not fully removed and remained as seen in FIG. 6A.

Referring to FIGS. 5B and 6B, the second electrode composition 282 is formed on the second dielectric layer 270 and in the opening Op. Referring to FIGS. 5C and 6C, after the co-firing process performed at high temperature, a eutectic layer 352 is formed in the opening Op, and the local back surface field 390 is formed. From FIGS. 5C and 6, it is apparent that, the thickness distribution of the local back surface field 390 adjacent to the neighboring silicon substrate 210 is not uniform in Comparative Examples. Especially at the edge E of the eutectic layer 352 in the Comparative Examples, there is a trend of edge thinning of the local back surface field 390 adjacent to the surface of the silicon substrate 210. Thus, the edge thinning of the local back surface field 390 makes the carrier at the edge leak easily and the carrier can not be effectively collected and utilized, which greatly reduces the conversion efficiency of the silicon solar cell 300.

In summary, by using the manufacturing method of silicon solar cell(s) provided in the present invention, the reaction area between the back electrode and the silicon substrate is increased, and voids generated in the junction (for example, aluminum silicon eutectic layer) of the back electrode and the silicon substrate are avoided. Also, full reaction occurs in the junction of the back electrode with the silicon substrate and the local back surface field of the silicon solar cell has a larger thickness, thus improving the efficiency of silicon solar cells. Furthermore, the edge(s) of the generated local back surface field of the silicon solar cell is relatively uniform, which further enhances the efficiency of the silicon solar cell. Further, since the laser L is used in the present invention to partially remove the second dielectric layer and a portion of the underlying silicon substrate so as to form the groove G, the groove formation is less likely to be affected by the surface morphology of the silicon substrate and the thickness of the dielectric layer. Hence, the manufacturing method of the silicon solar cell in the present invention has a larger process window, and high efficiency silicon solar cells may be produced at lower costs.

It will be apparent to those skilled in the art that various modifications and variations can be made to the structure of the present invention without departing from the scope or spirit of this disclosure. In view of the foregoing, it is intended that the present invention cover modifications and variations of this disclosure provided they fall within the scope of the following claims and their equivalents.

What is claimed is:

1. A method of manufacturing a silicon solar cell, comprising:
providing a silicon substrate, wherein a doped layer is formed on a light receiving surface of the silicon substrate;
forming a first dielectric layer on the light receiving surface;
forming a second dielectric layer on a rear surface of the silicon substrate opposite to the light receiving surface;
removing the second dielectric layer locally to form a patterned second dielectric layer and removing a portion of the silicon substrate to form at least one groove, wherein the patterned second dielectric layer exposes the at least one groove;
forming a first electrode composition on the light receiving surface and forming a second electrode composition on the rear surface, wherein the second electrode composition is at least partially filled into the at least one groove;
performing a high temperature process to co-firing the silicon substrate and the first electrode composition as well as the second electrode composition, so as to form a first electrode on the light receiving surface and a second electrode on the rear surface.

2. The method of claim 1, wherein forming the doped layer further comprises forming a high-concentration doped region and a low-concentration doped region in different regions of the doped layer on the light receiving surface.

3. The method of claim 2, wherein the high-concentration doped region is located on a region of the light receiving surface corresponding to the first electrode and a surface resistivity of the high-concentration doped region is equal to or less than 70 ohms/square.

4. The method of claim 2, wherein the low-concentration doped region is located on a region of the light receiving surface outside the region corresponding to the first electrode, and a surface resistivity of the low-concentration doped region is larger than 70 ohms/square.

5. The method of claim 2, wherein the high-concentration doped region and the low-concentration doped region are included on regions of the light receiving surface outside the region corresponding to the first electrode.

6. The method of claim 1, wherein a width of the at least one groove is greater than 5 microns and a depth of the at least one groove is greater than 0.5 microns.

7. The method of claim 1, wherein forming a first electrode composition on the light receiving surface comprises screen printing a silver paste on the light receiving surface, and forming a second electrode composition on the rear surface comprises screen printing an aluminum paste on the rear surface.

8. The method of claim 1, further comprising screen printing a silver paste on the rear surface to form a third electrode composition on the rear surface.

9. The method of claim 7, wherein the aluminum paste is screen printed to at least a portion of the at least one groove.

10. The method of claim 1, wherein the patterned second dielectric layer on the silicon substrate has at least one opening, and a pattern of the at least one opening of the second dielectric layer includes a line, a dot, a dashed line, a circular line, a polygon, an irregular shape or combinations thereof.

11. The method of claim 1, wherein a cross-sectional shape of the at least one groove along a thickness direction of the silicon substrate includes a square, a triangle, a circle, an oval, an arc, a multi-arc-shape, a polygon, an irregular shape or combinations thereof.

12. The method of claim 1, wherein after co-firing of the second electrode composition and the silicon substrate, a bottom contour of the at least one groove has an approximately symmetrical or substantially symmetrical shape along a thickness direction of the silicon substrate.

13. The method of claim 1, wherein the silicon substrate is a p-type silicon wafer, the p-type silicon wafer is a silicon wafer doped with boron or gallium ions, and the silicon wafer is a mono-crystalline silicon wafer or a multi-crystalline silicon wafer.

14. The method of claim 1, wherein the first dielectric layer is a single layer or a multilayer structure of SiO₂, SiₓN_{y}, SiₓN_{y}H_{z}, SiₓO_{y}N_{z}, SiC or a combination thereof.

15. The method of claim 1, wherein the second dielectric layer is a single layer or a multilayer structure of AlₓO_{y}, SiO₂, SiₓN_{y}, SiₓN_{y}H_{z}, SiₓO_{y}N_{z} or a combination thereof.

16. The method of claim 1, wherein a peak temperature of the co-firing process is greater than 600° C.

17. A silicon solar cell, which is fabricated by the manufacturing method of claim 1.

18. A silicon solar cell, comprising:
a silicon substrate, formed with a doped layer on a light receiving surface of the silicon substrate and a recess on the rear surface opposite to the light receiving surface, wherein the recess along a thickness direction of the silicon substrate has an approximately symmetrical or substantially symmetrical contour;
a first dielectric layer, disposed on the light receiving surface of the silicon substrate;
a patterned second dielectric layer, located on the rear surface of the silicon substrate, wherein the patterned second dielectric layer exposes the recess;
a first electrode, located on the light receiving surface; and
a second electrode, located on the rear surface, wherein a structure of a eutectic product from co-firing between the second electrode and the silicon substrate has a central depth smaller than its marginal depth.

19. The silicon solar cell of claim 18, wherein the doped layer further comprises at least a high-concentration doped region and a low-concentration doped region in different regions of the doped layer on the light receiving surface.

20. The silicon solar cell of claim 19, wherein the high-concentration doped region is located on a region of the light receiving surface corresponding to the first electrode and a surface resistivity of the high-concentration doped region is equal to or less than 70 ohms/square.

21. The silicon solar cell of claim 19, wherein the low-concentration doped region is located on a region of the light receiving surface outside the region corresponding to the first electrode, and a surface resistivity of the low-concentration doped region is larger than 70 ohms/square.

22. The silicon solar cell of claim 18, further comprising a third electrode, wherein the second electrode is an aluminum electrode on the rear surface, and the third electrode is a silver electrode on the rear surface.
